(19) United States
(12) Patent Application Publication
(10) Pub. No.: US 2010/0144140 A1
(43) Pub. Date: Jun. 10, 2010

(54) METHODS FOR DEPOSITING TUNGSTEN FILMS HAVING LOW RESISTIVITY FOR GAPFILL APPLICATIONS

(75) Inventors: Anand Chandrashekar, Sunnyvale, CA (US); Raashina Humayun, Freemont, CA (US); Michal Danek, Cupertino, CA (US)

Correspondence Address: Weaver Austin Villeneuve & Sampson LLP - NOVL;Attn.: Novellus Systems, Inc., P.O. Box 70250, Oakland, CA, 94612-0250, US

(73) Assignee: Novellus Systems, Inc., San Jose, CA (US)

(21) Appl. No.: 12/535,377

(22) Filed: Aug. 4, 2009

Related U.S. Application Data
(63) Continuation-in-part of application No. 12/332,017, filed on Dec. 10, 2008.

(51) Int. Cl. H01L 21/44

(52) U.S. Cl. 438/669; 257/E21.476

(57) ABSTRACT

Methods of filling gaps or recessed features on substrates are provided. According to various embodiments, the methods involve bulk deposition of tungsten to partially fill the feature followed by a removing a top portion of the deposited tungsten. In particular embodiments, the top portion is removed by exposing the substrate to activated fluorine species. By selectively removing sharp and protruding peaks of the deposited tungsten grains, the removal operation polishes the tungsten along the feature sidewall. Multiple deposition-removal cycles can be used to close the feature. The filled feature is less prone to coring during CMP.

### CROSS-REFERENCE TO RELATED APPLICATION

The present application is a continuation-in-part of and claims the benefit of priority to U.S. patent application Ser. No. 12/332,017, filed Dec. 10, 2008 and titled “METHOD FOR DEPOSITING TUNGSTEN FILM HAVING LOW RESISTIVITY, LOW ROUGHNESS AND HIGH REFLECTIVITY,” all of which is incorporated herein by reference in its entirety.

### BACKGROUND

The deposition of tungsten films using chemical vapor deposition (CVD) techniques is an integral part of many semiconductor fabrication processes. Tungsten films may be used as low resistivity electrical connections in the form of horizontal interconnects, vias between adjacent metal layers, and contacts between a first metal layer and the devices on the silicon substrate. In a conventional tungsten deposition process, the wafer is heated to the process temperature in a vacuum chamber, and then a very thin portion of tungsten film, which serves as a seed or nucleation layer, is deposited. Thereafter, the remainder of the tungsten film (the bulk layer) is deposited on the nucleation layer. Conventionally, the tungsten bulk layer is formed by the reduction of tungsten hexafluoride (WF₆) with hydrogen (H₂) on the growing tungsten layer.

### SUMMARY OF INVENTION

Methods of filling gaps or recessed features on substrates are provided. According to various embodiments, the methods involve bulk deposition of tungsten to partially fill the feature followed by a removing a top portion of the deposited tungsten. In particular embodiments, the top portion is removed by exposing the substrate to activated fluorine species. By selectively removing sharp and protruding peaks of the deposited tungsten grains, the removal operation polishes the tungsten along the feature sidewall. Multiple deposition-removal cycles can be used to close the feature. The filled feature is less prone to coring during CMP.

### BRIEF DESCRIPTION OF THE DRAWINGS

The following detailed description can be more fully understood when considered in conjunction with the drawings in which:

FIG. 1 is a process flow sheet showing relevant operations of methods according to various embodiments.

FIG. 2 is a schematic diagram illustrating the change in tungsten film grain structure after etching according to various embodiments.

FIG. 3 is a graph showing reflectivity as a function of film thicknesses for films formed by an embodiment of the methods described herein as compared to films formed by conventional CVD deposition.

FIG. 4 is a graph showing resistivity as a function of film thicknesses for films formed by an embodiment of the methods described herein as compared to films formed by conventional CVD deposition.

FIG. 5 is a process flow sheet showing relevant operations of methods according to various embodiments.

FIG. 6 is a schematic diagram illustrating tungsten fill using single step CVD methods and subsequent CMP coring that can occur due to seam formation.

FIGS. 7A and 7B illustrate fill of a feature at various stages in a method according to certain embodiments.

FIG. 8 is a process flow sheet showing relevant operations of methods according to various embodiments.

FIG. 9 is a schematic diagram illustrating a method of characterizing the profile of a partially filled feature.

FIG. 10 is a block diagram of a processing system suitable for conducting tungsten deposition processes in accordance with embodiments of the invention.

FIG. 11 is a diagram showing components of chamber suitable for carrying out tungsten deposition and etch-back processes in accordance with embodiments of the invention.

### DETAILED DESCRIPTION

Introduction

In the following description, numerous specific details are set forth in order to provide a thorough understanding of the present invention, which pertains to forming thin tungsten films. Modifications, adaptations or variations of specific methods and structures shown and discussed herein will be apparent to those skilled in the art and are within the scope of this invention.

Embodiments of the present invention involve depositing tungsten layers that have low resistivity and low roughness. In previous processes, resistivity and roughness of tungsten film have been inversely related; lowering resistivity results in increased roughness and vice-versa. As a result, percentage root mean square (RMS) roughness to film thickness may exceed 10% for low resistivity tungsten films of 500 Å or greater. Lowering the roughness of the film makes subsequent operations, including patterning, easier.

In certain embodiments, the methods described also provide highly reflective films. Conventional processes for depositing bulk tungsten layers involve hydrogen reduction of tungsten-containing precursors in chemical vapor deposition (CVD) processes. The reflectivity of a 1000A film that is grown by conventional hydrogen reduction CVD is 110% or less compared to that of a silicon surface. In certain applications, however, tungsten films having greater reflectivity are needed. For example, tungsten films having low reflectivity and high roughness can make photopatterning tungsten, e.g., to form bitlines or other structures, more difficult.

Methods of depositing reflective tungsten films having low resistivity that involve CVD deposition of tungsten in the presence of alternating nitrogen gas pulses are described in U.S. patent application Ser. No. 12/202,126, entitled “Method For Reducing Tungsten Roughness And Improving Reflectivity,” filed Aug. 29, 2008, and incorporated by reference herein. Other prior techniques for roughness reductions, reflectivity improvement or resistivity reduction involve modifying the process chemistry. In certain applications, however, the addition of nitrogen or other modifications to the process chemistry may be undesirable. For example, step coverage, plugfill degradation and electrical performance degradation due to the presence of incompatible elements arise from these bottom-up methods. The methods described herein, by contrast, can be used with any deposition chemistry without modification. In certain embodiments, for example, there is no nitrogen exposure during the deposition.

In certain embodiments, the methods provided herein involve bulk deposition of a tungsten layer via chemical vapor deposition on a substrate followed by an etch-back of a top portion of a deposited bulk layer. The resulting tungsten film has resistivity comparable to that of a film deposited by conventional large grain tungsten CVD processes, but with much higher reflectivity and lower roughness.

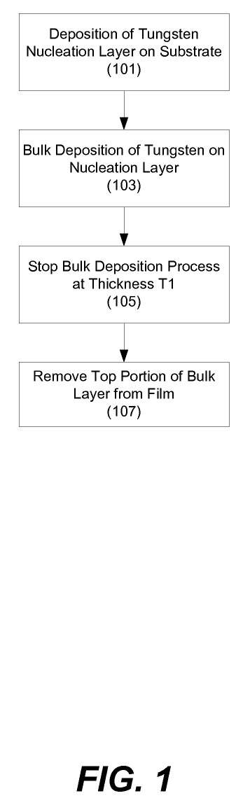

FIG. 1 shows a process according to certain embodiments of the invention. The process begins by depositing a tungsten nucleation layer on a substrate. Block 101. In general, a nucleation layer is a thin conformal layer which serves to facilitate the subsequent formation of a bulk material thereon. In certain embodiments, the nucleation layer is deposited using a pulsed nucleation layer (PNL) technique. In a PNL technique, pulses of the reducing agent, purge gases, and tungsten-containing precursors are sequentially injected into and purged from the reaction chamber. The process is repeated in a cyclical fashion until the desired thickness is achieved. PNL broadly embodies any cyclical process of sequentially adding reactants for reaction on a semiconductor substrate.

PNL techniques may be used in particular for the deposition of low resistivity films in small features. As features become smaller, the tungsten (W) contact or line resistance increases due to scattering effects in the thinner W film. While efficient tungsten deposition processes require tungsten nucleation layers, these layers typically have higher electrical resistivities than the bulk tungsten layers. Low resistivity tungsten films minimize power losses and overheating in integrated circuit designs. Because the ρ_{nucleation}>ρ_{bulk}, the thickness of the nucleation layer should be minimized to keep the total resistance as low as possible. The tungsten nucleation should also be sufficiently thick to fully cover the underlying substrate to support high quality bulk deposition.

PNL techniques for depositing tungsten nucleation layers that have low resistivity and that support deposition of low resistivity tungsten bulk layers are described in U.S. patent applications Ser. Nos. 12/030,645, 11/951,236 and 61/061,078, incorporated by reference herein. Additional discussion regarding PNL type processes can be found in U.S. Pat. Nos. 6,635,965, 6,844,258, 7,005,372 and 7,141,494 as well as in U.S. patent application Ser. No. 11/265,531, also incorporated herein by reference. In certain embodiments, low resistivity treatment operations are performed during or after the tungsten nucleation layer deposition. The methods described herein are not limited to a particular method of tungsten nucleation layer deposition, but include deposition bulk tungsten film on tungsten nucleation layers formed by any method including PNL, atomic layer deposition (ALD), CVD, and any other method.

Returning to FIG. 1, after the tungsten nucleation layer is deposited, and any desired treatment has been performed, a bulk tungsten layer of thickness T1 is deposited on the nucleation layer. Block 103. Thickness T1 is typically greater than the total desired thickness Td to account for the portion of the layer to be removed during the etch operation. In certain embodiments, bulk deposition involves a chemical vapor deposition (CVD) process in which a tungsten-containing precursor is reduced by hydrogen to deposit tungsten. While tungsten hexafluoride (WF6) is often used, the process may be performed with other tungsten precursors, including, but not limited to, WC16. In addition, while hydrogen is generally used as the reducing agent in the CVD deposition of the bulk tungsten layer, other reducing agents including silane may be used in addition or instead of hydrogen without departing from the scope of the invention. In another embodiment, W(CO)6 may be used with or without a reducing agent. Unlike with the PNL processes described above, in a CVD technique, the WF₆ and H₂ or other reactants are simultaneously introduced into the reaction chamber. This produces a continuous chemical reaction of mix reactant gases that continuously forms tungsten film on the substrate surface.

Once a layer having thickness T1 is deposited, the bulk deposition process is halted. Block 105. As discussed further below, T1 is greater than the final desired thickness Td. A top portion of the layer is then removed or etched back. Block 107. In certain embodiments, the etching process involves a plasma etch. This may involve introducing activated species (including radicals, ions and/or high energy molecules) from a remote plasma generator. In certain embodiments, the removal operation involves a fluorine-based plasma etch, e.g., a remote NF3 plasma etch. The extent of the etch-back is discussed further below, though in certain embodiments, about 10% of the layer deposited in operation 103 is removed.

The flow of fluorine activated species (or other species depending on the removal chemistry) is then shut off. Typically, the process is complete at this point if the deposited thickness after etch-back is the desired total thickness. In certain embodiments, at least one additional deposition-removal cycle is performed to deposit the tungsten layer.

The method described above produces films having higher reflectivity and lower roughness than films deposited by conventional methods having identical thicknesses. For example, in one experiment, reflectivity (as compared to a bare silicon wafer) of a 1940 Å film as deposited was 103%. After exposure to a remote NF3 plasma to remove 20 0 Å, reflectivity was 115%. By contrast, a 1720 Å film deposited by CVD with no etch back had a reflectivity of 106%. Additionally, resistivity of the etch tungsten film is lower than a conventionally deposited film of the same thickness—in certain embodiments, about 20% lower. This is significant because an increase in reflectivity is accompanied by an increase in resistivity in conventional methods.

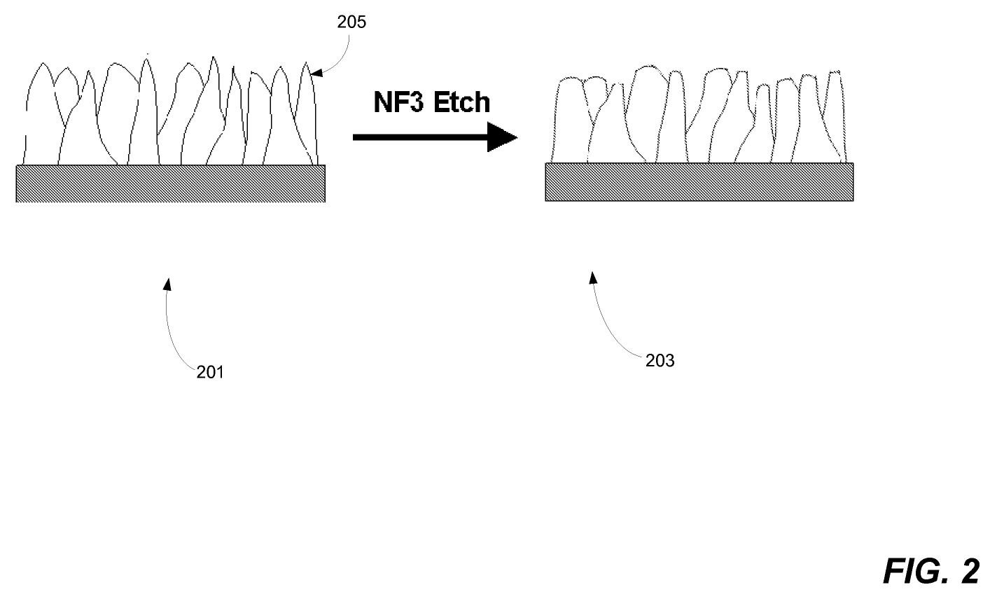

Typically, low resistivity is achieved by large grain growth, while smoothness and high reflectivity is achieved by using small grain deposition. Tungsten grain growth occurs in lateral and vertical directions. In certain embodiments, the methods described herein involve growing large grain tungsten in a bulk deposition process. After deposition, the vertically-oriented grain growth is selectively etched. After etching, the large laterally-oriented growth remains, providing low resistivity, while reflectivity is increased and roughness is significantly reduced. This is illustrated in FIG. 2, which shows schematic illustrations of the tungsten layer before (201) and after (203) a fluorine-based remote etched. The layer shown at 203 is about 90% as that shown in 201. Prior to the etch, sharp peaks, such as peak 205, are present. These peaks cause difficulties in subsequent lithographic patterning. After the etch, however, the grain profile is more flat, making the surface more reflective.

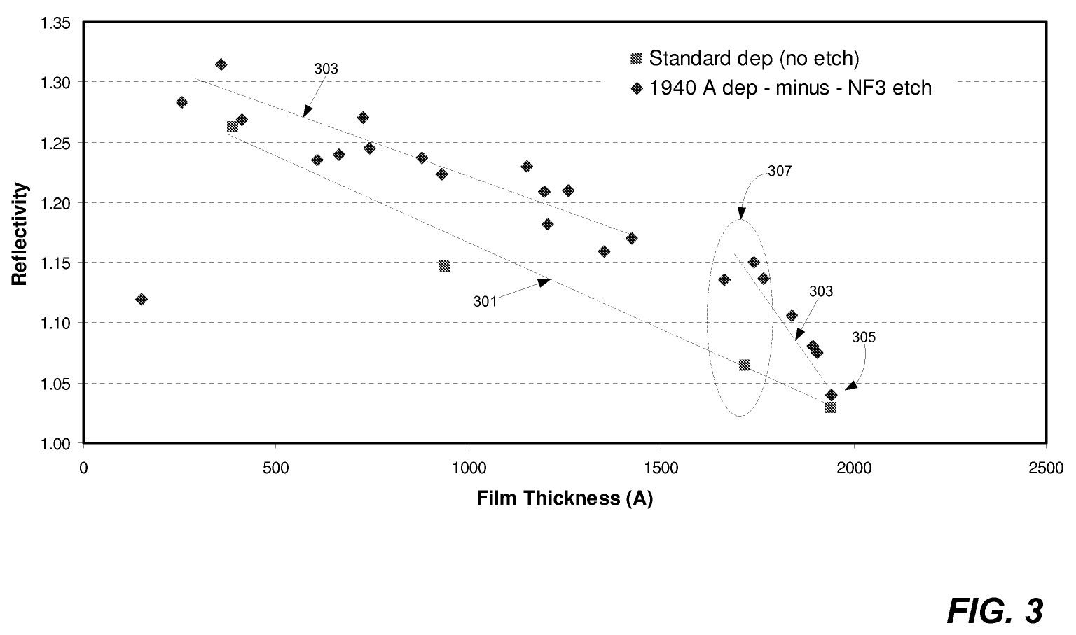

Not only does the etch process result in a more reflective surface compared to the unetched layer 201 as shown in FIG. 2, but resistivity and roughness are also improved for a film of comparable thickness. FIG. 3 is a graph showing reflectivity for films of various thicknesses as deposited by a conventional method (CVD deposition to the indicated thickness) and films as deposited by an embodiment of the invention (CVD deposition of 1940 Å+etch back to the indicated thickness). Rough trendlines 301 and 303 show reflectivity as a function of thickness for conventional deposition and for deposition+etch-back, respectively. As can be seen from the figure, there is a rapid increase in reflectivity, as compared to the conventional layer, from an insignificant portion etched (at 305) to about 200 Å etched. The improvement in reflectivity then flattens out as more film is etched. A maximum impact region (indicated at 307) shows the range of thicknesses removed in the etch operation that results in greatest improvement in reflectivity. This corresponds to about 10% of the as-deposited film thickness. Thus, in certain embodiments, the final film thickness is between about 75-95%, or more particularly, 80-95% of the as-deposited film thickness. Without being bound by a particular theory, it is believed that the maximum impact region etch-back corresponds to the peaks of the as-deposited film being removed. The top-down etch operation selectively removes the peaks because there is more surface area near the peaks of the as-deposited film. By stopping the etch process before the lower regions are etched, only the peaks are removed, leaving the lateral growth of the grains intact. As indicated, however, resistivity is unexpectedly also found to be lower following the etch process as compared to the same layers prior to etching. Without being bound by a particular theory, it is believed that this unexpected effect may be due to the grain boundaries being less defined after the etch operation. As discussed further below, in certain embodiments, resistivity is further improved (lowered) by using certain etch operation process conditions.

The removal operation may be any physical or chemical removal operation that can be used to remove a top portion of the as-deposited film. Etch chemistries that may be employed include fluorine-containing etch chemistries, including using xenon difluoride, molecular fluorine and nitrogen trifluoride. Bromine and chlorine-containing compounds, including nitrogen trichloride, molecular chlorine and molecular bromine. In certain embodiments, the etch may be a plasma etch. The plasma may be generated remotely or in the chamber. In a particular embodiment, NF3 is fed to a remote plasma generator. Activated species, including atomic fluorine, are generated within the remote plasma generator and flowed into the chamber for the chemical etch.

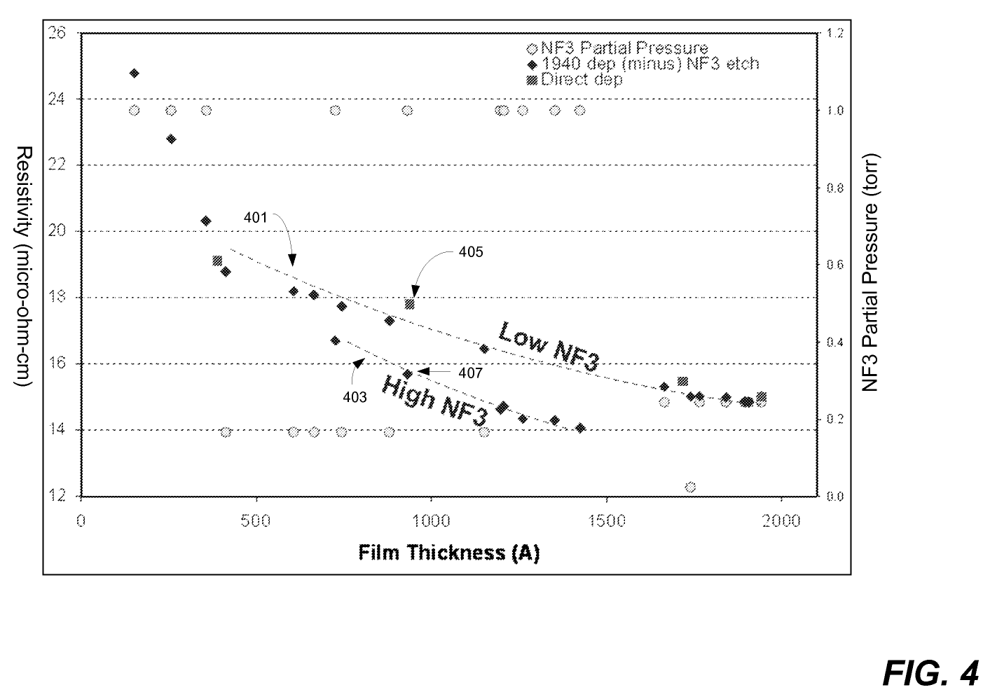

Etchant pressure has been found to affect film resistivity, with higher pressure resulting in lower resistivity. This effect is demonstrated in FIG. 4, which presents a graph showing resistivity of films of various thicknesses. Films deposited using conventional direct CVD deposition (squares) and films deposited to 1940 Å and etched to the indicated thickness (diamonds). The graph shows the partial pressure of the NF3 as introduced to the remote plasma generator for various thicknesses of films formed by deposition and etching. Curve 401 is a rough trendline showing resistivity as a function of thickness for films deposited using low NF3 partial pressure (0.17 and 0.24 Torr) and curve 403 is a rough trendline of showing resistivity as a function of thickness for films deposited using high NF3 partial pressure (1 Torr). Using high partial pressure results in films having lower resistivity. The improvement in resistivity is also seen comparing data points 405 and 407, representing reflectivity of a conventionally deposited film and a high NF3 etched film, respectively, both films of thickness about 930 Å. The conventionally deposited film has a resistivity of almost 18 micro-ohm-cm, whereas the high NF3 film has a resistivity of less than 16 micro-ohm-cm—a greater than 20% improvement.

In certain embodiments, the partial pressure of the etchant as introduced to a remote plasma generator is above 0.5 Torr, and as high as 80 Torr. In particular embodiments, the partial pressure of the etchant is about 1 Torr as flowed into the remote plasma generator, or deposition chamber.

Comparing the resistivity of the conventionally deposited films to that of etched films of comparable thicknesses (e.g., at about 400 Å and about 900 Å), the resistivity of the etched films is less than that of the conventionally deposited films. Resistivity improves for both high flow (high partial pressure) etchant as well as low flow (low partial pressure) etchant over conventionally deposited film. This is shown in the table below:

| | | | | Final |
|---|---|---|---|---|
| | As-deposited | Final | Resistivity as- | resistivity |
| | Thickness | Thickness | deposited | (micro- |
| Process | (Å) | (Å) | (micro-ohm-cm) | ohm-cm) |
| Conventional | 1720 | 1720 | 15.5 | 15.5 |
| Dep - Low | 1940 | 1740 | 15 | 15 |
| NF3 Etch | | | | |
| Conventional | 1350 | 1350 | 17 | 17 |
| (estimated | | | | |
| from | | | | |
| trendline) | | | | |
| Dep - High | 1940 | 1350 | 15 | 14.3 |
| NF3 Etch | | | | |

With conventional deposition, there is an inverse relationship between resistivity and thickness: resistivity decreases with increasing thickness. Using the methods described herein however, it is possible to obtain low resistivity thin films. This process may be used to deposit thin films having low resistivity, with final thin film thickness ranging according to various embodiments, from 100 Å to 1000 Å. For thin films, the final film thickness may be between 10%-90% of the as-deposited film, i.e., as much as 90% of the as-deposited film may be removed to create the low resistivity thin film.

In addition to chemical etching, the top portion may be removed in certain embodiments by sputtering, e.g., with argon, or by a very soft chemical mechanical planarization (CMP) method such as touch CMP.

In another embodiment, the chamber is simultaneously cleaned while the etch process takes place. By introducing a fluorine-based etchant into the chamber, tungsten deposited on the interior parts of the chamber may be removed while the deposited tungsten layer is etched. By simultaneously cleaning the chamber while etching, the necessity of independent chamber clean operations is reduced or eliminated.

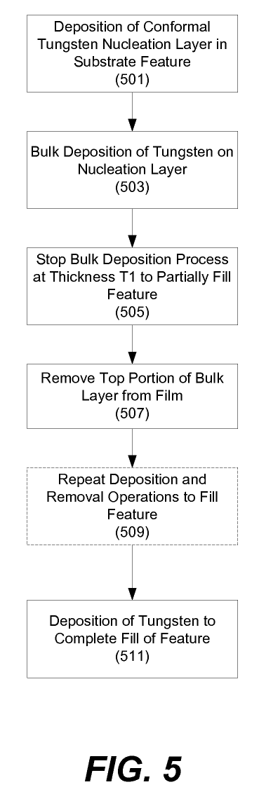

Applications of the processes described herein include forming bit line structures and trench line and via structures. According to various embodiments, deposition may be on a blanket or patterned wafer. For example, bit line processes typically involve deposition of a planar film of tungsten while trench line and via applications involve deposition of tungsten on a patterned wafer. FIG. 5 is a process flow diagram depicting operations in an embodiment of the processes described herein that uses multiple deposition cycles and in some cases multiple deposition-etch cycles. A nucleation layer may be deposited as described above with respect to FIG. 1. Block 501. In a recessed feature such as a trench, PNL or other technique is used to conformally deposit the nucleation layer. Bulk deposition of tungsten on the nucleation layer is then carried out to fill the feature. Block 503. Bulk deposition is then stopped at a thickness T1. Block 505. T1 is less than the desired thickness of the layer. In this process, T1 is a thickness at which the feature is only partially filled. For example, for a 1 micron feature (width), T1 is less than 0.5 microns, with roughly 0.5 microns being deposited thickness required to fill the feature. After the bulk deposition to partially fill the feature, the top portion of the deposited layer is then removed. Block 507. Here, the grains having protruding peaks are those oriented perpendicularly to the sidewall and may be selectively removed as described above with respect to FIG. 2. As with deposition, film removal is typically uniform throughout the feature, i.e., roughly the same thickness of tungsten is removed from the sidewall at the top of the feature as is removed deep within the feature. The deposition and removal operations are then optionally repeated one or more times to further fill the feature. Block 509. In certain embodiments, repeating the deposition and removal operations involves a bulk deposition, e.g., by CVD, directly on etched-back tungsten. Alternatively, another tungsten nucleation layer or other treatment operation may be performed after the removal operation prior to the bulk deposition. Once the one or more deposition-removal cycles have been completed, feature fill is completed by a deposition operation, such as a CVD operation. Block 511.

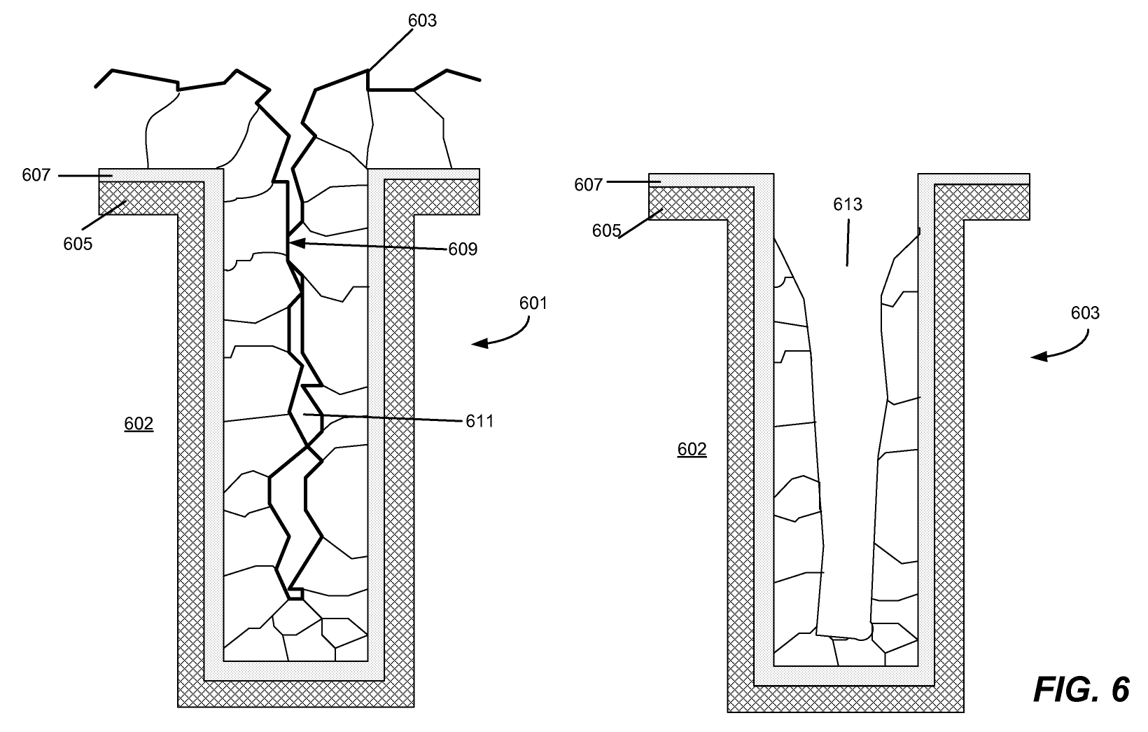

In certain embodiments, trench lines are filled by the processes described herein. Trenches, as well as other wide features, e.g., at micron or sub-micron dimensions, are prone to post-CMP coring. FIG. 6 depicts a trench line 601 filled by a single deposition (nucleation and bulk deposition). Trench line 601 is patterned in a wafer, e.g., in an oxide layer 602. One or more films 605 and 607 may be formed on the sidewalls and/or bottom of the trench. These films can include any of adhesion layers, barrier layers, etc. Examples of thin film material include titanium, titanium nitride, tantalum, tantalum nitride, tungsten, tungsten nitride, or combinations thereof. A tungsten nucleation layer (not shown) may be deposited conformally on the sidewalls and bottom of the trench to facilitate the formation of bulk tungsten. As is apparent, the schematic is representative and not too scale; for example, the trench width may be on the order of microns or tenths of microns with the nucleation layer on the order of tens of angstroms.

The tungsten grains 603 deposited by the CVD process are large and non-uniform. As described above, large grained tungsten films reduce tungsten film resistivity. While the tungsten fill step coverage can be excellent, post-CMP issues like coring can occur. The tungsten grains can grow into irregular and jagged shapes, an example of which is indicated at 609, resulting in formation of seams such as seam 611. The filled trench after CMP is shown at 603. The core or center of the feature is hollowed out at 613 due to the structural weakness presented by seam 607.

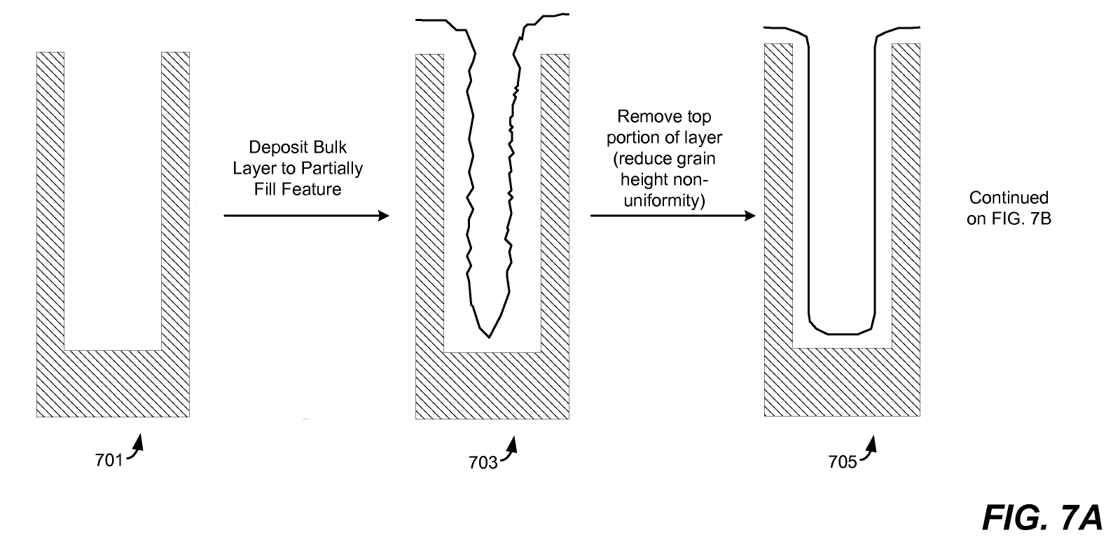

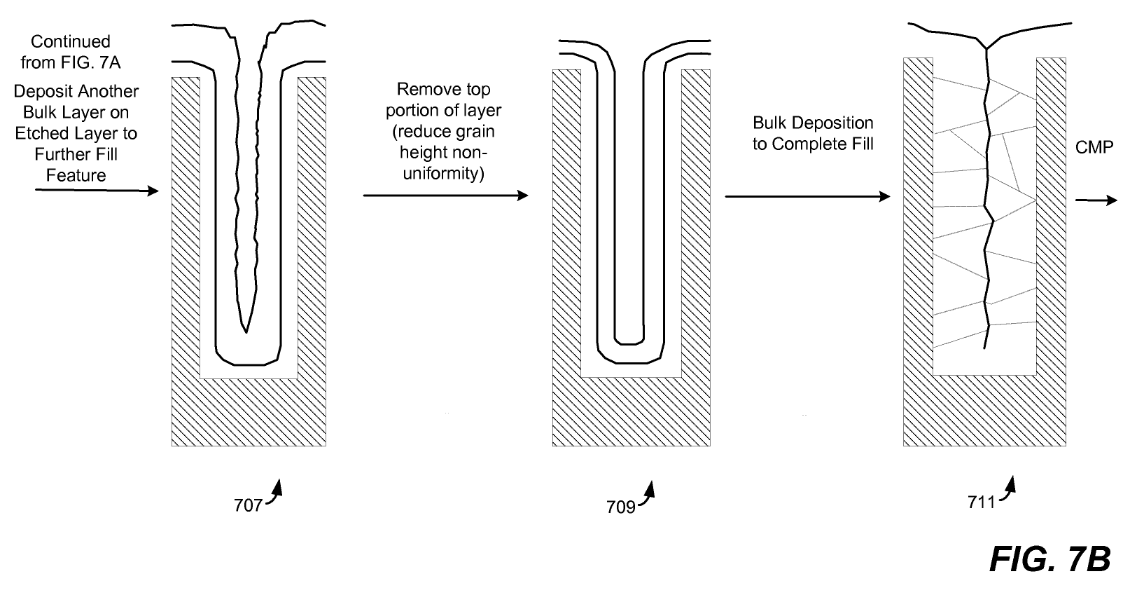

FIGS. 7A and 7B show representations of a feature during various stages of a fill process according to certain embodiments. First, in FIG. 7A, an unfilled feature is shown at 701. The recessed feature is typically one of many recessed features on a patterned wafer, and may be formed in a dielectric material or other layer formed during a fabrication process. According to various embodiments, the feature may be a via, trench or any other recessed feature. As indicated above, various films (not shown) may coat the sidewall and/or bottom of the feature, including barrier layers, adhesion layers, etc. Depending on the prior processing, the exposed sidewalls and bottom of the recessed feature may be smooth and uniform or may contain irregularities. In certain embodiments, the surface of the sidewalls differs from that of the bottom of the feature. According to various embodiments, the feature width may range from 10 Angstroms—10 microns, more particularly from 10 nm-1 micron. Exemplary aspect ratios are 2:1-30:1, 2:1-10:1, or 5:1-10:1.

A bulk deposition process is used to partially fill the feature. The partially filled feature is shown at 703. This process typically takes place by a chemical vapor deposition (CVD) method as described above. In certain embodiments, a nucleation layer is first deposited by a pulsed nucleation layer (PNL) method, atomic layer deposition (ALD) method, or other appropriate method. As indicated above, the layer is deposited to a thickness T1, which is greater than the total desired thickness of the layer (a sub-layer of the eventually filled feature) and less than the thickness required to fill the feature. In certain embodiments, the thickness T1 should be small enough that uneven grains do not meet at center interface closing off the feature. An example of this undesirable effect is depicted at 609 in FIG. 6. The deposited grains in the filled feature depicted at 703 are relatively large but have uneven heights.

The top portion of the layer is then removed as described above. As discussed with respect to FIG. 1, in certain embodiments, a chemical etch is performed. Also as discussed above, activated fluorine species from a remote plasma generator may be used. Typically, the removal process is purely chemical, i.e., there is no ion bombardment or sputtering effect. Remote plasma generation is useful in this regard as ions formed in the plasma generator are able to recombine. Volatile compounds containing tungsten and fluorine, e.g., WF6, are formed are pumped out.

The removal operation polishes the tungsten along the feature sidewall resulting in removal of sharp and protruding tungsten peaks. The result after removal is a tungsten layer having a smooth profile, as shown at 705. While grain heights are reduced by removal process, grain sizes remain the same so that tungsten resistivity is not increased.

Another bulk layer is then deposited. Depending on the size of the feature and the desired grain size, the feature may be completely filled at this juncture and ready for CMP. In the process depicted in FIGS. 7A and 7B, multiple deposition-removal cycles are used; accordingly the feature is only partially filled by the next bulk deposition. This is shown at 707 in FIG. 7B. The thickness to which the bulk layer is deposited (T2) may be the same as T1 or may be different. For example, in certain embodiments, as the gap grows narrower due to the previously deposited sub-layers, the thickness of the as-deposited bulk layer may be reduced. As described above, the thickness should be such that the feature remains open.

The top portion of the just-deposited layer is then removed as shown at 709. This polishes the layer and provides a smooth surface for the next deposition. Multiple deposition-removal cycles may be performed if appropriate at this point. In the depicted process, fill is completed by a final bulk deposition. Because the amount of deposited film is relatively small, the grain height of this bulk layer is more uniform than if the deposition was performed in a single operation as depicted in FIG. 6. The filled feature is depicted at 711. The grains grown from each sidewall are even and form an even interface with no seam. A CMP process may then be performed removing the tungsten deposited above the feature, while leaving the feature completely filled. According to various embodiments, the amount of material removed in each removal operation may range from about 5% of the total thickness of the tungsten film to over 50% or in certain cases 80% of the thickness.

While grain heights are reduced due to the etch process, grain sizes remain the same so that tungsten resistivity is not increased. In certain embodiments, tungsten resistivity in the feature is reduced due to the replacement of voids and seams with tungsten that contributes to electron transport. Resistivity may also be lowered by forming larger tungsten grain sizes in the direction of electron transport. Also in certain embodiments, tungsten films that are more compacted are obtained, thereby resulting in the ability to modulate tungsten film density and in turn to modulate CMP rates.

As indicated above, in certain embodiments during the removal process, tungsten is etched uniformly throughout the feature. To do this, deposition is limited during the partial fill such that the feature is not prematurely closed off or blocked by large grains. In addition, the removal process conditions are such that the removal operates in a reaction-limited, rather than mass-transport limited, regime. While this depends on the feature dimensions and processing apparatus, in general, lower temperatures and higher flow rates are used. Wafer temperatures between about 250-450° C. and NF₃ flow rates (into a remote plasma generator) between about 750-4000 sccm may be used. One of skill in the art will realize that these ranges may be varied to obtain conditions at which the reaction is not limited by diffusion. In addition, chemical etch operations that do not involve sputtering or bombardment allow for uniform removal.

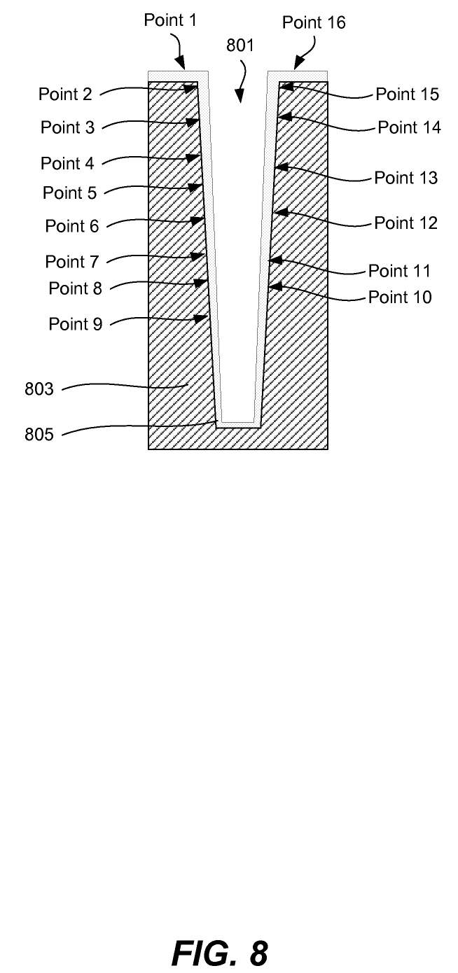

In many embodiments, the feature profile is uniform prior to the tungsten deposition and/or after the tungsten deposition such that there is no significant overhang at the feature entrance. In certain embodiments, the average thickness throughout the feature varies by no more than 30%, or in certain embodiments, 25% or 10%. This also may be characterized by comparing the average thickness within the feature to the average thickness at the top of the feature. Average thickness in the feature as normalized by the average thickness at the top of the feature may range in certain embodiments, from 80%-120%, or more particularly, 90%-110%, or 95%-105%. In certain cases, when values of certain parameters (e.g., thicknesses) are specified at these positions/areas, these values represent averages of multiple measurements taken within these positions/areas. Examples of measuring points are shown in FIG. 8, which depicts a schematic representation of the feature 801 in a substrate 803, with locations of the measuring points of tungsten layer 805 thickness indicated as “Point 1,” “Point 2,” etc. Thickness values may be normalized to a value on the field region (points 1 and 16) or an average thereof. Points 2-15 or a subset thereof may be averaged to find the thickness within the feature.

In certain embodiments, if a substrate is provided having a re-entrant profile or overhang at the top of the feature, the re-entrant profile will remain after an initial bulk deposition operation. In such cases, an initial removal operation to selectively remove tungsten at the top of the feature may be performed prior to successive deposition-etch cycles as described herein. Selective removal of tungsten deposited at the top of a feature is described in U.S. patent application Ser. No. ______, (Attorney Docket No. NOVLP315/NVLS-3464) filed concurrently herewith and incorporated by reference herein.

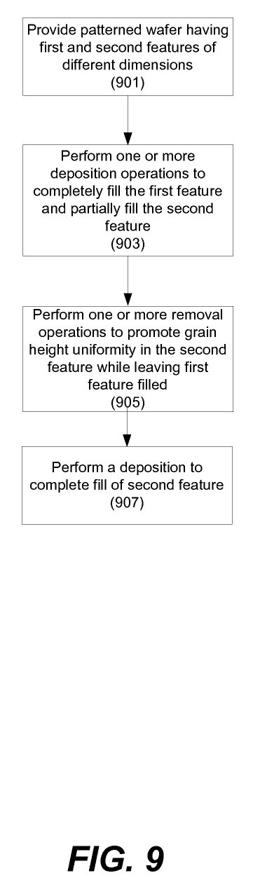

In certain embodiments, the removal operations described herein may be used to promote grain height uniformity and reduce roughness of partially filled features while leaving any previously filled features intact. FIG. 9 shows a process flow diagram depicting operations according to another embodiment in which features of different sizes are filled. First a patterned wafer having first and second features of different dimensions is provided. Block 901. One or more deposition operations are then performed to completely fill the first (typically smaller) feature and partially fill the second (typically larger) feature. Block 903. According to various embodiments, the one or more deposition operations may or may not involve intervening etch operations. After the first feature is filled, one or more removal operations are performed to promote grain height uniformity in the second feature, e.g., as depicted above with respect to FIGS. 7A and 7B. Block 905. Deposition operations in deposition-removal cycles are performed as necessary. The first feature remains filled, i.e., the removal operations do not re-open the feature. A final deposition operation is then performed as described above with respect to FIG. 7B to complete fill of the second feature. Block 907. Thus, the method preferentially etches sidewall tungsten only in larger features, after the smaller features have closed. This may be useful in dual damascene processes.

### Experimental

Tungsten films were deposited on tungsten nucleation layers on semiconductor wafers using a conventional hydrogen reduction of WF6 CVD process. Films of 389 Å, 937 Å, 1739 Å and 1942 Å (center thickness) were deposited. Reflectivity and resistivity were measured for all films.

Tungsten films were deposited on tungsten nucleation layers using a deposition-etch process in accordance with that described in FIG. 1. A hydrogen reduction of WF6 CVD process was used to deposit the films. Deposition conditions were the same as for the conventionally deposited films. As deposited thickness for all films was about 1940 Å (ranging from 1935 Å to 1947 Å). A remote NF3 plasma was used to etch the films, with etch amounts ranging from 1 Å to 1787 Å, resulting in final thicknesses ranging from 151 Å to 1941 Å. NF3 partial pressure was set at one of the following levels: 0.02 Torr, 0.17 Torr, 0.24 Torr or 1 Torr. Reflectivity and resistivity were measured for all films after etching.

Reflectivity improves by about 10% after etch as compared to conventionally deposited films of comparable thickness. Results of the reflectivity measurements are shown in FIG. 3 and discussed above.

Results of the resistivity measurements are shown in FIG. 4 and discussed above.

Roughness is also improved over the conventionally deposited films. For example, AFM roughness of a 1940 Å film as deposited was 9.7 nm. After NF3 etch of about 20 nm to 1740 Å, roughness was reduced by 2.5 nm to 9.2 nm. Roughness of a conventionally deposited 1720 Å film was 9 nm. Roughness is improved by about 20% over the conventionally deposited films.

In another example, about 800 Angstroms (target) of tungsten was deposited to obtain partial fill in 0.25 μm trenchlines (6:1 AR) by a CVD process. Remotely activated fluorine species (from an NF3 flow) were used to etch the deposited tungsten from the feature using the following process conditions:

| | | | | | Approximate |
|---|---|---|---|---|---|
| | | NF3 Flow | Pressure | Etch Time | Thickness |
| Process | Temp (C.) | (sccm) | (Torr) | (secs) | Removed |
| 1 | 250 | 750 | 8 | 15 | 100 |
| 2 | 250 | 750 | 8 | 30 | 200 |
| 3 | 300 | 1375 | 6 | 7 | 200 |
| 4 | 300 | 1375 | 6 | 15 | 450 |
| 5 | 350 | 2000 | 8 | 4 | 250 |

Between about 10% to over 50% of the top portion of the deposited layer was removed during the etch operation. Grain height non-uniformity was measured for a trenchline prior to etch and after etch process 4. Grain height non-uniformity was reduced by the etch operation from 13.5% to 6.3%. After re-deposition, grain height non-uniformity was found to remain uniform (7.2% after a first re-deposition, and 5.7% after a second re-deposition.) No additional etch operations were performed, i.e., only one etch operation was performed with no etch between re-deposition and the second re-deposition.

### Apparatus

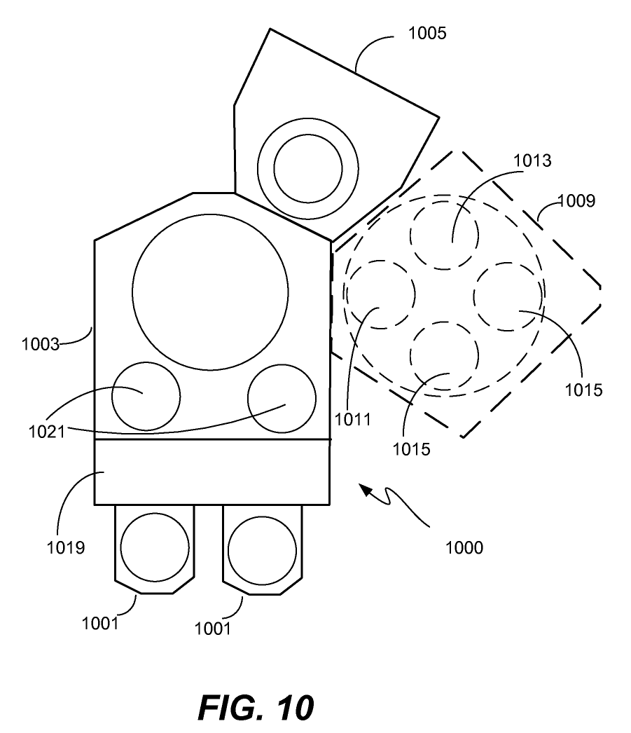

FIG. 10 is a block diagram of a processing system suitable for conducting tungsten deposition processes in accordance with embodiments of the invention. The system 1000 includes a transfer module 1003. The transfer module 1003 provides a clean, pressurized environment to minimize the risk of contamination of substrates being processed as they are moved between the various reactor modules. Mounted on the transfer module 1003 is a multi-station reactor 1009 capable of performing PNL deposition and CVD according to embodiments of the invention. Chamber 1009 may include multiple stations 1011, 1013, 1015, and 1017 that may sequentially perform these operations. For example, chamber 1009 could be configured such that station 1011 performs PNL deposition, station 1013 performs a nucleation layer treatment, and stations 1013 and 1015 perform CVD and etch operations. Alternatively, the etch operation may be performed in a different station as the CVD deposition. In certain embodiments, the deposition and etch operations may be performed in separate tools.

Also mounted on the transfer module 1003 may be one or more single or multi-station modules 1007 capable of performing plasma or chemical (non-plasma) pre-cleans. The module may also be used for various other treatments, e.g., post liner tungsten nitride treatments. The system 1000 also includes one or more (in this case two) wafer source modules 1001 where wafers are stored before and after processing. An atmospheric robot (not shown) in the atmospheric transfer chamber 1019 first removes wafers from the source modules 1001 to loadlocks 1021. Å wafer transfer device (generally a robot arm unit) in the transfer module 1003 moves the wafers from loadlocks 1021 to and among the modules mounted on the transfer module 1003.

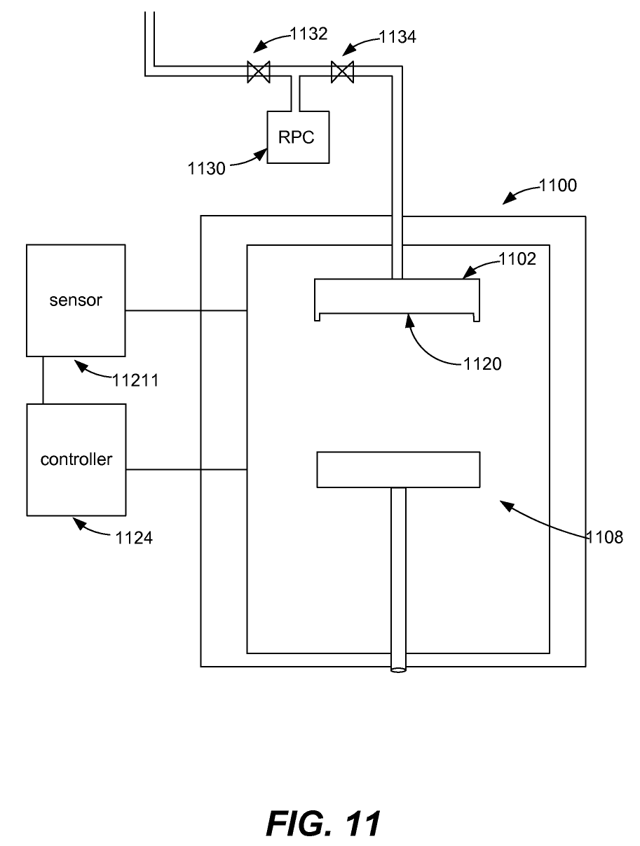

FIG. 11 shows a schematic representation of a chamber or station that may be used in an etch operation. The methods of the invention involve introducing an etchant, e.g., fluorine-based etchant into a reactor or chamber 1100, having a pedestal 1108 that supports a wafer on which tungsten is deposited. Atomic fluorine is generated in a remote plasma chamber 1130. In operation, a fluorine-containing gas, e.g., NF₃, is introduced to the remote plasma chamber 1130 via a valve 1132. Atomic fluorine is generated therein. Valve 1134 is opened to allow the atomic species to enter the chamber via the showerhead 1102. FIG. 11 shows just one example of a remote plasma chamber; other arrangements and configurations may be used. Atomic species enter the chamber and etch the tungsten film (not shown) deposited on the wafer as discussed above. (One of skill in the art will understand that other species may be present in the plasma or gases exiting the showerhead into the reactor. For example, the species entering the deposition chamber from the showerhead may include NF₃ and NFₓ as well as atomic fluorine. No ions or electrons are present in significant amounts. At higher pressures, NF₃ as well as F₂ is present.) By appropriately adjusting the pressure, the showerhead acts as a tunable source of the desired atomic and/or molecular fluorine etchant. Note that preceding the etch process, deposition precursors may enter the showerhead to deposit the tungsten film on the wafer.

Sensors 1126 represent gas sensors, pressure sensors etc. that may be used to provide information on reactor conditions. Examples of chamber sensors that may be monitored during the clean include mass flow controllers, pressure sensors such as manometers, thermocouples located in pedestal, and infra-red detectors to monitor the presence of a gas or gases in the chamber.

As the tungsten is removed from the chamber, tungsten hexafluoride is produced. The tungsten hexafluoride may be sensed by sensors 1126, providing an indication of the progress of the etch. The tungsten hexafluoride is removed from the reactor via an outlet (not shown) such that once the clean is complete, the sensor will sense no tungsten hexafluoride. Sensors 1126 may also include a pressure sensor to provide chamber pressure readings.

Molecular fluorine may be supplied to the chamber by methods other than using a remote plasma chamber to generate atomic fluorine and regulating the pressure so that the atomic fluorine combines into molecular fluorine as described above. For example, fluorine gas may allowed into the chamber from a fluorine gas supply. However, in embodiments that employ both atomic and molecular fluorine as described above, the use of the remote plasma chamber provides a simple way to switch between stages. Moreover, the remote plasma chamber allows the use of NF₃, which is easier to handle than molecular fluorine, as an inlet gas to the system. Certain embodiments may employ a direct (in-situ) plasma for the generation of atomic fluorine.

In certain embodiments, a system controller 1124 is employed to control process conditions during deposition and removal operations. The controller will typically include one or more memory devices and one or more processors. The processor may include a CPU or computer, analog and/or digital input/output connections, stepper motor controller boards, etc.

The controller may control all of the activities of the deposition apparatus. The system controller executes system control software including sets of instructions for controlling the timing, mixture of gases, chamber pressure, chamber temperature, wafer temperature, RF power levels, wafer chuck or pedestal position, and other parameters of a particular process. Other computer programs stored on memory devices associated with the controller may be employed in some embodiments.

Typically there will be a user interface associated with the controller. The user interface may include a display screen, graphical software displays of the apparatus and/or process conditions, and user input devices such as pointing devices, keyboards, touch screens, microphones, etc.

The computer program code for controlling the deposition and removal processes in a process sequence can be written in any conventional computer readable programming language: for example, assembly language, C, C++, Pascal, Fortran or others. Compiled object code or script is executed by the processor to perform the tasks identified in the program.

The controller parameters relate to process conditions such as, for example, process gas composition and flow rates, temperature, pressure, remote plasma conditions such as RF power levels and the low frequency RF frequency, etchant flow rates or partial pressure, cooling gas pressure, and chamber wall temperature. These parameters are provided to the user in the form of a recipe, and may be entered utilizing the user interface.

Signals for monitoring the process may be provided by analog and/or digital input connections of the system controller. The signals for controlling the process are output on the analog and digital output connections of the deposition apparatus.

The system software may be designed or configured in many different ways. For example, various chamber component subroutines or control objects may be written to control operation of the chamber components necessary to carry out the inventive deposition processes. Examples of programs or sections of programs for this purpose include substrate positioning code, process gas control code, pressure control code, heater control code, and plasma control code.

A substrate positioning program may include program code for controlling chamber components that are used to load the substrate onto a pedestal or chuck and to control the spacing between the substrate and other parts of the chamber such as a gas inlet and/or target. A process gas control program may include code for controlling gas composition and flow rates and optionally for flowing gas into the chamber prior to deposition in order to stabilize the pressure in the chamber. A pressure control program may include code for controlling the pressure in the chamber by regulating, e.g., a throttle valve in the exhaust system of the chamber. A heater control program may include code for controlling the current to a heating unit that is used to heat the substrate. Alternatively, the heater control program may control delivery of a heat transfer gas such as helium to the wafer chuck. An etchant control program may include code for controlling the etchant flow rate and partial pressure, carrier gas flow rate and partial pressure, etch time, etc.

Examples of chamber sensors that may be monitored during deposition include mass flow controllers, pressure sensors such as manometers, and thermocouples located in pedestal or chuck. Appropriately programmed feedback and control algorithms may be used with data from these sensors to maintain desired process conditions. Tungsten hexafluoride, or other etching byproduct, may be sensed to provide an indication of how much tungsten has been removed.

The foregoing describes implementation of embodiments of the invention in a single or multi-chamber semiconductor processing tool.

### Applications

The present invention may be used to deposit thin, low resistivity tungsten layers for many different applications. One application is for interconnects in integrated circuits such as memory chips and microprocessors. Interconnects are current lines found on a single metallization layer and are generally long thin flat structures. These may be formed by a blanket deposition of a tungsten layer (by a process as described above), followed by a patterning operation that defines the location of current carrying tungsten lines and removal of the tungsten from regions outside the tungsten lines.

A primary example of an interconnect application is a bit line in a memory chip. Of course, the invention is not limited to interconnect applications and extends to vias, contacts and other tungsten structures commonly found in electronic devices.

In certain embodiments wherein the deposition process is used for bit line applications, the final thickness of the tungsten film is between 500 Å -2000 Å, with as-deposited film thicknesses between 500 Å-2500 Å. The process may also be used to deposit much thicker films if needed. Also as described above, the process may be used to deposit thin films having low resistivity, e.g., films of thickness between 100 Å-1000 Å. In general, the invention finds application in any environment where thin, low-resistivity tungsten layers are required.

### Other Embodiments

While this invention has been described in terms of several embodiments, there are alterations, modifications, permutations, and substitute equivalents, which fall within the scope of this invention. It should also be noted that there are many alternative ways of implementing the methods and apparatuses of the present invention. For example, although the above description describes primarily CVD deposition, the deposition-etch methods may also be employed with other types of tungsten deposition. It is therefore intended that the following appended claims be interpreted as including all such alterations, modifications, permutations, and substitute equivalents as fall within the true spirit and scope of the present invention.

What is claimed is:

1. A method of depositing tungsten on substrate in a deposition chamber, the method comprising:
introducing a tungsten-containing precursor and a reducing agent to the deposition chamber;
depositing a first layer of tungsten on the substrate via a first chemical vapor deposition reaction between the tungsten-containing precursor and the reducing agent;
removing a top portion of the deposited tungsten layer to form an etched tungsten layer; and after forming the etched tungsten layer, depositing a second layer of tungsten on the substrate via a second chemical vapor deposition reaction.

2. The method of claim 1 wherein the substrate is a patterned substrate having a recessed feature and the tungsten layers are deposited within the feature to thereby wholly or partially fill the recessed feature with tungsten.

3. The method of claim 1 wherein removing the top portion of the deposited tungsten layer comprises etching between about 5% and 80% of the top thickness of the deposited tungsten layer.

4. The method of claim 1 wherein removing the top portion of the deposited tungsten layer comprises etching at least about 10% of the top thickness of the deposited tungsten layer.

5. The method of claim 1 further comprising introducing a fluorine-containing compound to a remote plasma generator upstream of the deposition chamber, generating atomic fluorine within the remote plasma generator, and flowing atomic fluorine from the remote plasma generator to the deposition chamber to remove the top portion of the deposited tungsten layer.

6. The method of claim 5 wherein the fluorine-containing compound is NF3.

7. The method of claim 1 wherein the feature has an opening of at least about 10 nm wide.

8. The method of claim 1 wherein removing a top portion of the tungsten layer comprises selectively removing portions of tungsten grains oriented perpendicularly to the surface on which the grains are deposited.

9. A method of filling a recessed feature with tungsten, wherein the recessed feature is on a substrate in a deposition chamber, comprising:
depositing a tungsten layer via a chemical vapor deposition reaction to partially fill the feature;
removing a top portion of the deposited tungsten layer to form an etched tungsten layer; and
after removing the top portion, depositing tungsten via a chemical vapor deposition reaction to further fill the feature.

10. The method of claim 9 wherein the top portion is removed uniformly throughout the feature.

11. The method of claim 9 wherein depositing tungsten via a chemical vapor deposition reaction to further fill the feature comprises at least one further deposition-removal cycle.

12. The method of claim 9 wherein further filling the feature comprises completely filling the feature.

13. The method of claim 9 wherein the feature width is about 10 nm to 1 um.

14. The method of claim 9 wherein removing a top portion of the deposited tungsten layer comprises a reaction rate-limited etch process.

15. The method of claim 9 wherein removing the top portion comprises a chemical reaction producing and removing a tungsten-containing volatile product.

16. The method of claim 9 wherein the average thickness of the etched layer at the opening is within about 10% of the average thickness of the etched layer inside the feature.

17. The method of claim 9 wherein removing a top portion of the deposited tungsten layer to form an etched tungsten layer comprises etching the sidewalls of the recessed feature.

18. The method of claim 1 wherein the substrate includes a second feature filled with tungsten and wherein tungsten is removed selectively from the sidewalls of the recessed feature without removing tungsten from the second feature.
